(19) United States
(12) Patent Application Publication
(10) Pub. No.: US 2007/0182436 A1
(43) Pub. Date: Aug. 9, 2007

(54) Technique for offsetting signal lines from the glass weave of resin/glass materials

(75) Inventors: Michael C. Freda, Morgan Hill, CA (US); Derek Tsai, Sunnyvale, CA (US)

Correspondence Address: OSHA LIANG L.L.P./SUN, 1221 MCKINNEY, SUITE 2800, HOUSTON, TX, 77010, US

(73) Assignee: Sun Microsystems, Inc., Santa Clara, CA (US)

(21) Appl. No.: 11/349,591

(22) Filed: Feb. 7, 2006

(51) Int. Cl. G01R 31/26

(52) U.S. Cl. 324/765

(57) ABSTRACT

A technique for offsetting an orientation of signal lines in a printed circuit board involves rotating the printed circuit board prior to or as the signal lines are fabricated in the printed circuit board. Such offsetting results in a printed circuit board in which the signal lines are not orthogonal with an arrangement of woven glass fibers formed in the printed circuit board.

### BACKGROUND

A computer system 10, as shown in FIG. 1, includes several components that are collectively used by a user to perform various functions such as, for example, preparing and generating a document with a word processor application. With the computer system 10, the user may input data to a computing portion 12 using peripheral devices such as a keyboard 14 or a mouse 16. Data may also be provided to the computing portion 12 using data storage media (e.g., a floppy disk or a CD-ROM (not shown)). The computing portion 12, using memory and other internal components, processes both internal data and data provided to the computing portion 12 by the user to generate data requested by the user. The generated data may be provided to the user via, for example, a display device 18 or a printer 20. The computing portion 12 of a computer system typically includes various components such as, for example, a power supply, disk drives, and the electrical circuitry required to perform the necessary and requested operations of the computer system.

As shown in FIG. 2, the computing portion 12 may contain a plurality of circuit boards 22, 24, 26, 28 (e.g., printed circuit boards (PCBs) or printed wiring boards (PWBs)) on which various circuit components are implemented. For example, a computing portion designed to have enhanced sound reproducing capabilities may have a circuit board dedicated to implementing circuitry that specifically operate to process data associated with the reproduction of sound.

In FIG. 2, the components of exemplary circuit board 22 are shown. A crystal oscillator 30 provides a reference of time to various integrated circuits (ICs) 32, 34, 36, 38, 40, 42 (e.g., application specific integrated circuits (ASICs), field-programmable gate arrays (FPGAs), microprocessors, logic gates) that are connected to the circuit board 22. The integrated circuits 32, 34, 36, 38, 40, 42 communicate with one another, i.e., pass data, using wires or traces of conductive material (e.g., copper (shown, but not labeled)) embedded in the circuit board 22.

As described above with reference to FIG. 2, electrical systems often use a number of integrated circuits that are mounted on a printed circuit board. Each integrated circuit includes a number of leads that extend from the packaging of the integrated circuit. The leads of the various integrated circuits are interconnected to allow signals to be passed between the integrated circuits such that the system performs some function. For example, a personal computer includes a wide variety of integrated circuits, e.g., a microprocessor and memory chips, that are interconnected on one or more printed circuit boards in the computer.

Those skilled in the art will note that FR4 is the usual base material from which printed circuit boards are constructed. “FR” means Flame Retardant, and Type “4” indicates woven glass reinforced epoxy resin. The laminate is constructed of woven glass fibers impregnated with epoxy resin (also known as “pre-preg”) and copper foil. In other words, FR4 laminate is a composite of a continuous glass woven fabric base impregnated with an epoxy resin binder. Further, a range of dielectric constants is associated with an FR4-type laminate.

### SUMMARY

According to one aspect of one or more embodiments of the present invention, a method of fabrication comprises: rotating a printed circuit board having woven glass fibers orthogonally aligned with an edge of the printed circuit board; and fabricating a signal routing in the printed circuit board.

According to another aspect of one or more embodiments of the present invention, a computer system comprises: a printed circuit board; and a plurality of integrated circuits disposed on the printed circuit board, wherein the plurality of integrated circuits are operatively connected by a routing of signal traces through the printed circuit board, where the routing of signal traces is not orthogonal with an arrangement of woven glass fibers formed in the printed circuit board.

According to another aspect of one or more embodiments of the present invention, a method of performing computer system operations comprises: passing signals from a first integrated circuit to a second integrated circuit through a signal routing fabricated in a printed circuit board on which the first integrated circuit and the second integrated circuit are disposed, where an orientation of the signal routing is rotated relative to an orthogonal alignment of the signal routing with the printed circuit board.

Other aspects of the present invention will be apparent from the following description and the appended claims.

### BRIEF DESCRIPTION OF DRAWINGS

FIG. 1 shows a computer system.

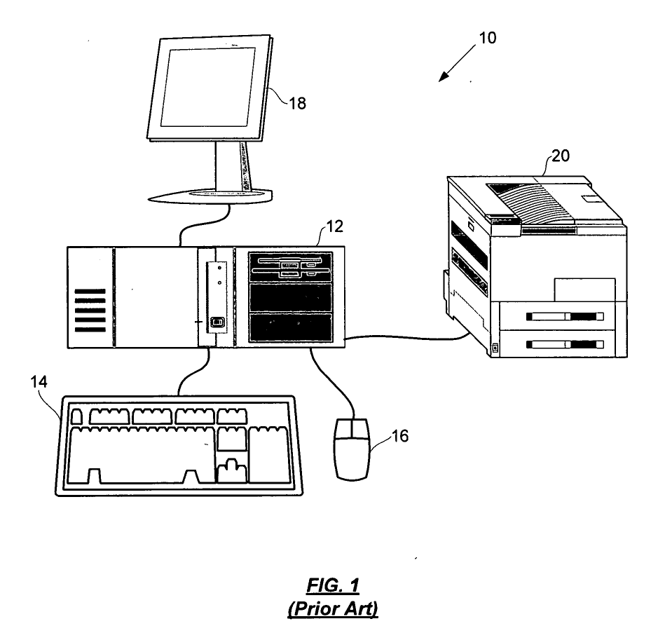

FIG. 2 shows a portion of a computer system.

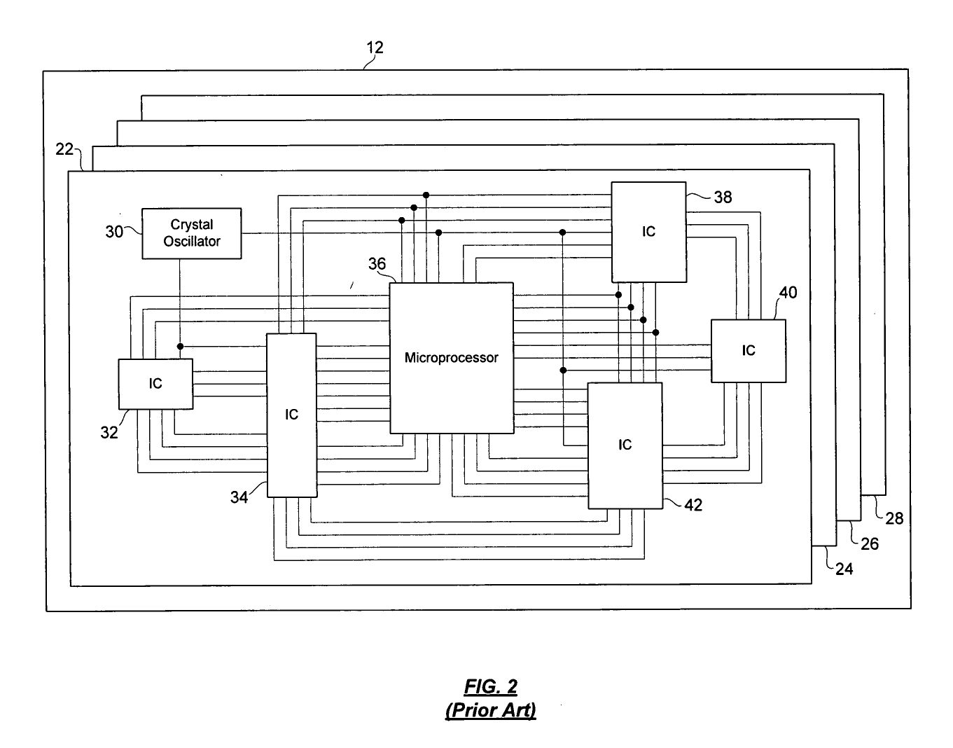

FIG. 3 shows a technique in accordance with an embodiment of the present invention.

### DETAILED DESCRIPTION

As described above, an FR4-based printed circuit board is built of woven glass fibers impregnated with an epoxy resin. In general, pure epoxy has a dielectric constant (ε=˜3.0) that is lower than a dielectric constant (ε=˜5.8) of pure glass. Thus, signal lines or traces incorporated in the printed circuit board located over a higher density of epoxy in the FR4 laminate experience a lower dielectric constant than signal lines or traces incorporated in the printed circuit board located over a higher density of glass in the FR4 laminate. Accordingly, the propagation delay and impedance of signal lines or traces depend on the orientation of the signal lines or traces relative to an area of the FR4 laminate that is epoxy-rich versus an area of the FR4 laminate that is glass-rich.

Due to the effect described above, a signal may experience an effective dielectric constant that ranges from ˜3.5 to ˜5.0 on epoxy/glass laminate materials depending upon the location of the signal line relative to the glass-weave orientation. The speed of signal propagation depends upon the effective dielectric constant which the signal is surrounded by according to the following equation:

$$propagation delay = \sqrt{\frac{ɛ}{c}} ,$$

where ε represents the dielectric constant, and where c represents the speed of light. Thus, due to differences in effective dielectric constants experienced by differing signals, one signal may reach an intended destination prior to another signal, effectively resulting in skew. In other words, the difference in signal speed between one signal line and another signal line due to different relative orientations to glass- or epoxy-rich areas of the laminate results in the signals reaching an intended destination at different times. Those skilled in the art will note that as clock speeds increase, there is less tolerance for signal skew.

Specific embodiments of the present invention will now be described in detail with reference to the accompanying figures. Like elements in the various figures are denoted by like reference numerals for consistency. Further, in the following detailed description of embodiments of the present invention, numerous specific details are set forth in order to provide a more thorough understanding of the present invention. In other instances, well-known features have not been described in detail to avoid obscuring the description of embodiments of the present invention.

Embodiments of the present invention relate to a technique for reducing or eliminating skew resulting from differences in effective dielectric constants experienced by signals in a printed circuit board laminate. In one or more embodiments of the present invention, a standard orthogonal signal routing is fabricated on a printed circuit board that is rotated by some value.

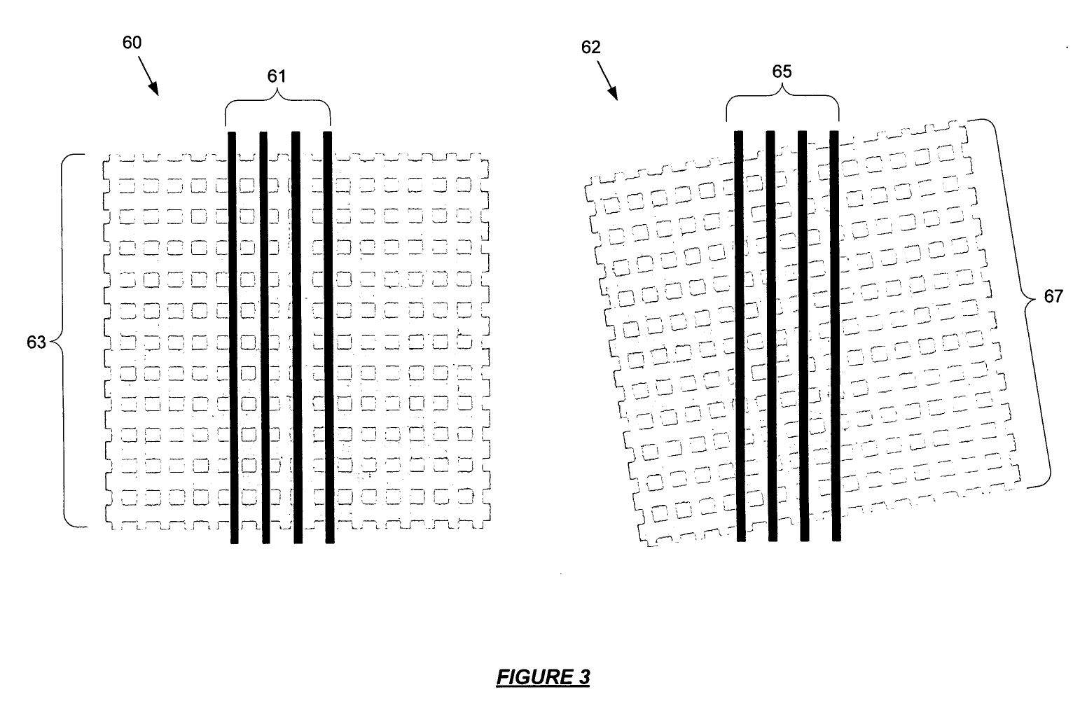

FIG. 3 shows an example of a technique in accordance with an embodiment of the present invention. In an initial orientation 60, a signal routing 61 is designed to be fabricated on/in a printed circuit board laminate having woven glass fibers 63 orthogonally aligned with edges of the printed circuit board. As such, the signal routing 61 would be disposed in an orthogonal alignment with the woven glass fibers 63.

In an improved orientation 62, the printed circuit board laminate is rotated (i.e., offset from that shown in the initial orientation 60) by some value. For example, in one or more embodiments of the present invention, a rotation may be of 0.1 inches for an 18 by 24 inch board.

Rotating the printed circuit board laminate results in the signal lines 65 fabricated therein to be offset and run over alternating resin-rich and glass-rich areas of the printed circuit board laminate. In other words, the rotation causes the signal routing 65 to not be orthogonal with the woven glass fibers 67 in the printed circuit board. Accordingly, such an orientation has the effect of averaging out the propagation delay and minimizing its effect among signals. In other words, more signals propagate over alternating areas of the printed circuit board laminate, thereby causing an “averaging out” effect of the effective dielectric constants experienced by the signals. This results in a reduction or elimination of skew as the difference in effective dielectric constants experienced by two or more signals is reduced or eliminated due to the signals being subject to the “averaging out” effect caused by the rotated orientation of the printed circuit board laminate.

In one or more embodiments of the present invention, a printed circuit board may itself be rotated prior to fabrication therein of signal traces. Further, in one or more other embodiments of the present invention, a fabrication panel on which a printed circuit board laminate is resting may be rotated as to achieve a desired orientation of fabricated signal lines relative to the glass-weave of the printed circuit board laminate.

Further, in one or more embodiments of the present invention, instead of mainly using an epoxy as the resin in a printed circuit board material, the resin may be any one of polyimide, cyanate ester, teflon, polyphenelene oxide, polyphenelene ether, bismaleimide-triazine (BT), or a combination thereof. In general, one or more embodiments of the present invention may be used and practiced with any resin that has a different dielectric constant than reinforcing fibers in a printed circuit board.

Advantages of the present invention may include one or more of the following. In one or more embodiments of the present invention, an effect of dielectric constants inherent in a printed circuit board laminate may be reduced or minimized.

In one or more embodiments of the present invention, a technique that offsets signal lines relative to a glass weave of a printed circuit board laminate may result in a reduction or minimization of the effect of differing dielectric constants within the printed circuit board laminate.

In one or more embodiments of the present invention, improved signal performance may be achieved without the use of special materials or special design routing constraints.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

What is claimed is:

1. A method of fabrication, comprising:
rotating a printed circuit board having woven glass fibers orthogonally aligned with an edge of the printed circuit board; and
fabricating a signal routing in the printed circuit board.

2. The method of claim 1, the rotating comprising:
rotating a fabrication panel on which the printed circuit is disposed.

3. The method of claim 1, wherein the printed circuit board is formed of FR4 laminate.

4. The method of claim 1, wherein the woven glass fibers comprise a resin material.

5. The method of claim 4, wherein the resin material is formed at least in part of at least one of epoxy, polyimide, cyanate ester, teflon, polyphenelene oxide, bismaleimide-triazine, and polyphenelene ether.

6. The method of claim 4, wherein the resin material has a dielectric constant value that is different than a dielectric constant value of a glass material in the woven glass fibers.

7. A computer system, comprising:
a printed circuit board; and
a plurality of integrated circuits disposed on the printed circuit board, wherein the plurality of integrated circuits are operatively connected by a routing of signal traces through the printed circuit board,
wherein the routing of signal traces is not orthogonal with an arrangement of woven glass fibers formed in the printed circuit board.

8. The computer system of claim 7, wherein the printed circuit board is rotated relative to an orthogonal alignment of the printed circuit board with the routing of signal traces.

9. The computer system of claim 7, wherein the printed circuit board is formed of FR4 laminate.

10. The computer system of claim 7, wherein the printed circuit board comprises glass and a resin material.

11. The computer system of claim 10, wherein the resin material is formed at least in part of at least one of epoxy, polyimide, cyanate ester, teflon, polyphenelene oxide, bismaleimide-triazine, and polyphenelene ether.

12. The computer system of claim 10, wherein the resin material has a dielectric constant value that is different than a dielectric constant value of the glass.

13. The computer system of claim 7, wherein the woven glass fibers are orthogonal with at least one edge of the printed circuit board.

14. A method of performing computer system operations, comprising:
passing signals from a first integrated circuit to a second integrated circuit through a signal routing fabricated in a printed circuit board on which the first integrated circuit and the second integrated circuit are disposed,
wherein an orientation of the signal routing is rotated relative to an orthogonal alignment of the signal routing with the printed circuit board.

15. The method of claim 14, wherein the printed circuit board is formed of FR4 laminate.

16. The method of claim 14, wherein the printed circuit board comprises glass and a resin material.

17. The method of claim 16, wherein the resin material is formed at least in part of at least one of epoxy, polyimide, cyanate ester, teflon, polyphenelene oxide, bismaleimide-triazine, and polyphenelene ether.

18. The method of claim 16, wherein the resin material has a dielectric constant value that is different than a dielectric constant value of the glass material.
